(19) United States
(12) Patent Application Publication
(10) Pub. No.: US 2020/0235171 A1
(43) Pub. Date: Jul. 23, 2020

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventor: Weilong ZHOU, Beijing (CN)

(21) Appl. No.: 16/648,478

(22) PCT Filed: May 21, 2019
(86) PCT No.: PCT/CN2019/087672

§ 371 Date: Mar. 18, 2020

(30) Foreign Application Priority Data
May 31, 2018 (CN) 201810549069.8

(51) Int. Cl. H01L 27/32; H01L 51/50

(52) U.S. Cl. CPC H01L 27/3211; G09G 3/3225; H01L 51/5072; H01L 51/5056

(57) ABSTRACT

A display panel includes first color sub-pixels, second color sub-pixels and third color sub-pixels in an array arranged in a first direction and a second direction intersecting the first direction. The first color sub-pixels include a first type of first color sub-pixel of which a first transport layer has a first thickness and a second type of first color sub-pixel of which the first transport layer has a second thickness. The first type of first color sub-pixels are arranged into a plurality of first sub-arrays, each including at least one respective sub-pixel of the first type of first color sub-pixels. The second type of first color sub-pixels are arranged into a plurality of second sub-arrays, each including at least one respective sub-pixel of the second type of first color sub-pixels. The first sub-arrays and the second sub-arrays are alternately arranged in the first direction and the second direction.

### CROSS REFERENCE TO RELATED APPLICATIONS

The present application claims the benefit of Chinese Patent Application No. 201810549069.8, filed on May 31, 2018, the entire disclosure of which is incorporated herein by reference.

### TECHNICAL FIELD

The present disclosure relates to the field of display technology, and in particular, to a display panel and a display apparatus.

### BACKGROUND

Organic light emitting diodes (OLEDs) are devices that make organic materials emit light under the action of an electric field, and are featured by high contrast, ultra-thin flexibility, short response time, etc. It has been found, however, that OLED displays presenting white pictures have color differences when viewed at different angles of view. The reason for the color difference can be explained as follows.

The International Commission on Illumination (CIE) in 1931 theoretically assumed three primary colors that do not exist in nature, namely the theoretical three primary colors, represented by X, Y, and Z, forming a XYZ color measurement system. The X primary color corresponds to red-violet having a higher saturation than the spectral red, the Y primary color corresponds to green having a higher saturation than the spectral green having a wavelength of 520 nm, and the Z primary color corresponds to blue having a higher saturation than the spectral blue having a wavelength of 477 nm. The stimuli of these three theoretical primary colors are expressed as X, Y, and Z, which are the so-called tristimulus values. The tristimulus values are calculated according to the following formulas:

X=∫₃₈₀⁷⁸⁰x̅(λ)Φ(λ)dλ,

Y=∫₃₈₀⁷⁸⁰y̅(λ)Φ(λ)dλ,

Z=∫₃₈₀⁷⁸⁰z̅(λ)Φ(λ)dλ,

where x̅(λ), y̅(λ) and z̅(λ) are the spectral tristimulus values, respectively, and Φ(λ) is the spectrum.

The OLED includes an anode, a cathode, and an organic light emitting material sandwiched between the anode and the cathode, with the anode and the cathode forming a microcavity. Due to a microcavity effect, the spectra Φ(λ) of the red, green, and blue colors will differ at different angles of view, resulting in a change in the tristimulus value XYZ, and then a color shift of the display screen.

### SUMMARY

According to some embodiments of the present disclosure, a display panel is provided which comprises first color sub-pixels, second color sub-pixels and third color sub-pixels in an array arranged in a first direction and a second direction intersecting the first direction. Each of the first, second and third color sub-pixels comprising an anode, a cathode opposite to the anode in a thickness direction of the display panel, and a hole transport layer, a light emitting layer, and an electron transport layer sandwiched between the anode and the cathode and stacked one by one. The first color sub-pixels comprise a first type of first color sub-pixel in which a first transport layer has a first thickness and a second type of first color sub-pixel in which the first transport layer has a second thickness, the second thickness being different from the first thickness. The first transport layer comprises at least one selected from a group consisting of the hole transport layer and the electron transport layer. The first type of first color sub-pixels are arranged into a plurality of first sub-arrays. Each of the first sub-arrays comprises at least one respective sub-pixel of the first type of first color sub-pixels. The second type of first color sub-pixels are arranged into a plurality of second sub-arrays. Each of the second sub-arrays comprises at least one respective sub-pixel of the second type of first color sub-pixels. The plurality of first sub-arrays and the plurality of second sub-arrays are alternately arranged in the first direction and the second direction.

According to some embodiments, each of the first sub-arrays comprises one respective sub-pixel of the first type of first color sub-pixels. Each of the second sub-arrays comprises one respective sub-pixel of the second type of first color sub-pixels.

According to some embodiments, each of the first sub-arrays comprises at least two respective sub-pixels, adjacent in the first direction, of the first type of first color sub-pixels. Each of the second sub-arrays comprises at least two respective sub-pixels, adjacent in the first direction, of the second type of first color sub-pixels.

According to some embodiments, each of the first sub-arrays comprises at least two respective sub-pixels, adjacent in the second direction, of the first type of first color sub-pixels. Each of the second sub-arrays comprises at least two respective sub-pixels, adjacent in the second direction, of the second type of first color sub-pixels.

According to some embodiments, each of the first sub-arrays comprises an array of m×n respective sub-pixels of the first type of first color sub-pixels, the m×n respective sub-pixels being adjacent to each other in the first direction and the second direction. Each of the second sub-arrays comprises an array of m×n respective sub-pixels of the second type of first color sub-pixels, the m×n respective sub-pixels being adjacent to each other in the first direction and the second direction, where m≥2 and n≥2.

According to some embodiments, an absolute value of a difference between the first thickness and the second thickness is less than 220 angstroms.

According to some embodiments, the second color sub-pixels comprise a first type of second color sub-pixel in which the first transport layer has a third thickness and a second type of second color sub-pixel in which the first transport layer has a fourth thickness, the fourth thickness being different from the third thickness. The first type of second color sub-pixels are arranged into a plurality of third sub-arrays. Each of the third sub-arrays comprises at least one respective sub-pixel of the first type of second color sub-pixels. The second type of second color sub-pixels are arranged into a plurality of fourth sub-arrays. Each of the fourth sub-arrays comprises at least one respective sub-pixel of the second type of second color sub-pixels. The plurality of third sub-arrays and the plurality of fourth sub-arrays are alternately arranged in the first direction and the second direction.

According to some embodiments, each of the third sub-arrays comprises one respective sub-pixel of the first type of second color sub-pixels. Each of the fourth sub-arrays comprises one respective sub-pixel of the second type of second color sub-pixels.

According to some embodiments, each of the third sub-arrays comprises at least two respective sub-pixels, adjacent in the first direction, of the first type of second color sub-pixels. Each of the fourth sub-arrays comprises at least two respective sub-pixels, adjacent in the first direction, of the second type of second color sub-pixels.

According to some embodiments, each of the third sub-arrays comprises at least two respective sub-pixels, adjacent in the second direction, of the first type of second color sub-pixels. Each of the fourth sub-arrays comprises at least two respective sub-pixels, adjacent in the second direction, of the second type of second color sub-pixels.

According to some embodiments, each of the third sub-arrays comprises an array of m×n respective sub-pixels of the first type of second color sub-pixels, the m×n respective sub-pixels being adjacent to each other in the first direction and the second direction. Each of the fourth sub-arrays comprises an array of m×n respective sub-pixels of the second type of second color sub-pixels, the m×n respective sub-pixels being adjacent to each other in the first direction and the second direction, where m≥2 and n≥2.

According to some embodiments, an absolute value of a difference between the third thickness and the fourth thickness is less than 220 angstroms.

According to some embodiments, the third color sub-pixels comprise a first type of third color sub-pixel in which the first transport layer has a fifth thickness and a second type of third color sub-pixel in which the first transport layer has a sixth thickness, the sixth thickness being different from the fifth thickness. The first type of third color sub-pixels are arranged into a plurality of fifth sub-arrays. Each of the fifth sub-arrays comprises at least one respective sub-pixel of the first type of third color sub-pixels. The second type of third color sub-pixels are arranged into a plurality of sixth sub-arrays. Each of the sixth sub-arrays comprises at least one respective sub-pixel of the second type of third color sub-pixels. The plurality of fifth sub-arrays and the plurality of sixth sub-arrays are alternately arranged in the first direction and the second direction.

According to some embodiments, each of the fifth sub-arrays comprises one respective sub-pixel of the first type of third color sub-pixels. Each of the sixth sub-arrays comprises one respective sub-pixel of the second type of third color sub-pixels.

According to some embodiments, each of the fifth sub-arrays comprises at least two respective sub-pixels, adjacent in the first direction, of the first type of third color sub-pixels. Each of the sixth sub-arrays comprises at least two respective sub-pixels, adjacent in the first direction, of the second type of third color sub-pixels.

According to some embodiments, each of the fifth sub-arrays comprises at least two respective sub-pixels, adjacent in the second direction, of the first type of third color sub-pixels. Each of the sixth sub-arrays comprises at least two respective sub-pixels, adjacent in the second direction, of the second type of third color sub-pixels.

According to some embodiments, each of the fifth sub-arrays comprises an array of m×n respective sub-pixels of the first type of third color sub-pixels, the m×n respective sub-pixels being adjacent to each other in the first direction and the second direction. Each of the sixth sub-arrays comprises an array of m×n respective sub-pixels of the second type of third color sub-pixels, the m×n respective sub-pixels being adjacent to each other in the first direction and the second direction, where m≥2 and n≥2.

According to some embodiments, an absolute value of a difference between the fifth thickness and the sixth thickness is less than 220 angstroms.

According to some embodiments, the first color, the second color, and the third color are selected from respective different ones of red, green, and blue.

According to some embodiments of the present disclosure, a display apparatus is provided, comprising any one of the display panels described above.

### BRIEF DESCRIPTION OF THE DRAWINGS

FIG. 1 is a schematic diagram showing a structure of an OLED of a sub-pixel in a display panel according to an embodiment of the present disclosure;

FIGS. 2A to 2C are plan views schematically showing display panels according to embodiments of the present disclosure;

FIGS. 3A to 3C are plan views schematically showing display panels according to embodiments of the present disclosure;

FIGS. 4 to 6 are schematic diagrams showing improvement in color shift of the display panel of FIG. 2A compared to a conventional display panel; and

FIG. 7 is a block diagram schematically showing a display apparatus according to an embodiment of the present disclosure.

### DETAILED DESCRIPTION

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another. Thus, a first element, component, region, layer or section discussed below could be termed a second element, component, region, layer or section without departing from the teachings of the present disclosure.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. Terms such as “before” or “preceding” and “after” or “followed by” may be similarly used, for example, to indicate an order in which light passes through the elements. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present. In no event, however, should “on” or “directly on” be construed as requiring a layer to completely cover an underlying layer.

Embodiments of the disclosure are described herein with reference to schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

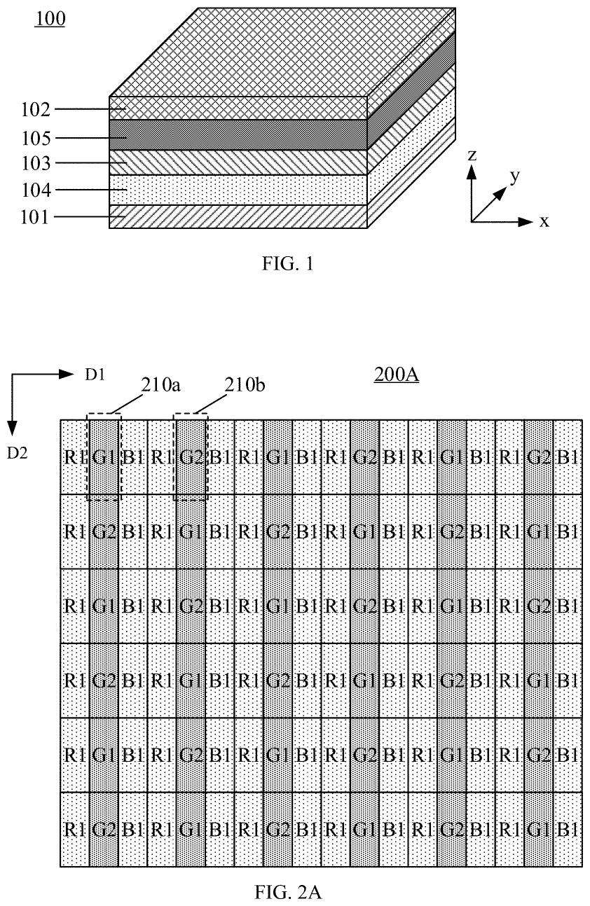

FIG. 1 is a schematic diagram showing a structure of an OLED 100 of a sub-pixel in a display panel according to an embodiment of the present disclosure.

Referring to FIG. 1, the OLED 100 has a layered structure including an anode 101, a hole transport layer 104, a light emitting layer 103, an electron transport layer 105, and a cathode 102. These layers extend along an x-y plane and are stacked one by one in a z direction. The z direction can be considered as a thickness direction of the display panel. In this thickness direction, the cathode 102 and the anode 101 face each other to form a microcavity. The hole transport layer 104, the light emitting layer 103, and the electron transport layer 105 are sandwiched between the anode 101 and the cathode 102 and stacked one by one. Depending on the material forming the light emitting layer 103, the OLED 100 may emit light of a corresponding color (for example, red, green, or blue) when being excited.

Although not shown, a plurality of such OLEDs 100 may be arranged in an array to form light emitting elements of respective sub-pixels of a display panel. Typically, the cathodes 102 of individual OLEDs are not patterned into separate blocks, but instead form a complete layer across the display panel. Here, for clarity of illustration, other structures in the display panel, such as a pixel circuit electrically connected to the OLED 100 and a base substrate on which the pixel circuit is formed, are not shown.

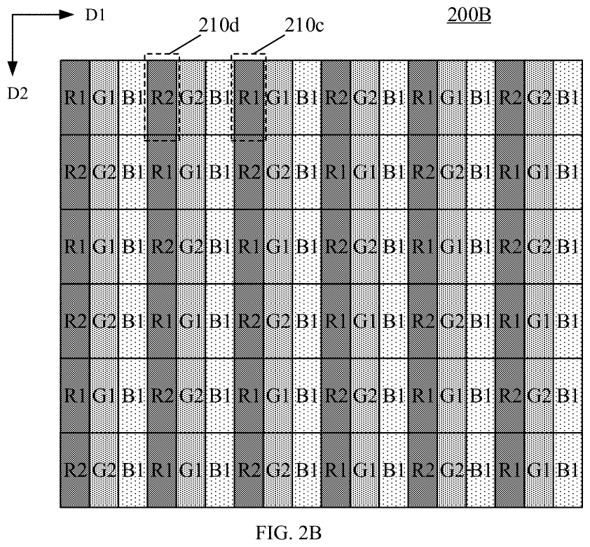

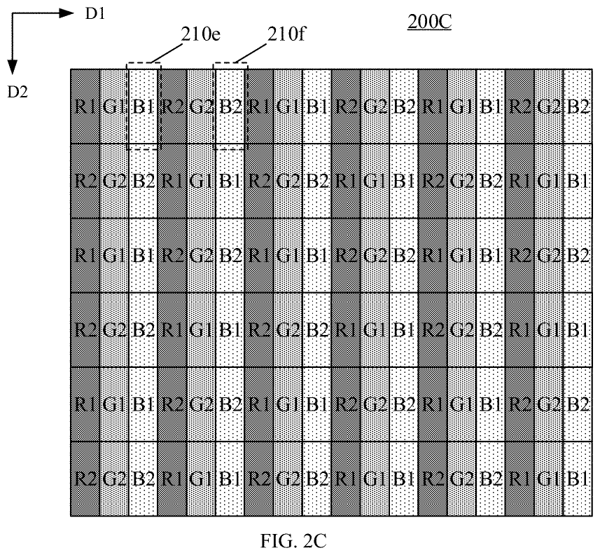

FIG. 2A is a plan view schematically showing a display panel 200A according to an embodiment of the present disclosure.

Referring to FIG. 2A, the display panel 200A includes first color sub-pixels G, second color sub-pixels R, and third color sub-pixels B that are in an array arranged in a first direction D1 and a second direction D2 intersecting (e.g., perpendicular to) the first direction D1. Each of these sub-pixels includes an OLED 100 as described above.

Each sub-pixel is indicated by a combination of a letter (“R”, “G” or “B”) and a number (“1” or “2”), with the letter indicating the color of the light emitted by the light-emitting layer 103 in the sub-pixel when being excited, and the number indicating the type of the transport layer in the sub-pixel that is associated with the thickness. For example, G1 indicates a green sub-pixel of the first type in which the transport layer (specifically, the hole transport layer 104 and/or the electron transport layer 105) has a first thickness, and G2 indicates a green sub-pixel of the second type in which the transport layer (specifically, the hole transport layer 104 and/or the electron transport layer 105) has a second thickness.

Herein, in a case where the transport layer refers to a hole transport layer 104, the term thickness refers to the thickness of the hole transport layer 104. In a case where the transport layer refers to an electron transport layer 105, the term thickness refers to the thickness of the electron transport layer 105. In a case where the transport layer refers to both a hole transport layer 104 and an electron transport layer 105, the term thickness refers to the sum of the thicknesses of both the hole transport layer 104 and the electron transport layer 105.

The second thickness is different from the first thickness. In some embodiments, an absolute value of a difference between the first thickness and the second thickness is less than 10% of the distance between the anode and the cathode of an OLED in a conventional display panel, such as 220 angstroms. In some embodiments, an absolute value of a difference between the first thickness and the second thickness is in a range from 110 angstroms to 132 angstroms.

In the example of FIG. 2A, the display panel 200A includes green sub-pixels G1 of a first type and green sub-pixels G2 of a second type, red sub-pixels R1 of a single type, and blue sub-pixels B1 of a single type. The first type of green sub-pixels G1 are arranged into a plurality of first sub-arrays 210a, each of which includes one respective sub-pixel of the first type of green sub-pixels G1. The second type of green sub-pixels G2 are arranged into a plurality of second sub-arrays 210b, each of which includes one respective sub-pixel of the second type of green sub-pixels G2. The plurality of first sub-arrays 210a and the plurality of second sub-arrays 210b are alternately arranged in both the first direction D1 and the second direction D2.

Due to different transport layer thicknesses, the microcavities formed by the first and second types of green sub-pixels G1 and G2 have different vertical sizes. This allows to adjust the color shift curve of a single color (specifically, green), and thus is expected to improve the color shift of mixed colors. In addition, a change in the thickness of a transport layer does not affect the display effect of a display panel since the transport layer is used to transport carriers (holes and/or electrons). In some embodiments, in view that an electron transport layer 105 is generally located above a light emitting layer 103 and thus a change in the thickness of the electron transport layer 105 may affect the characteristics of the light emitting layer 103, it may be suitable to change only the thickness of a hole transport layer 104.

It will be understood that although the display panel 200A is shown as having a sub-pixel arrangement pattern of Real RGB, this is merely exemplary and illustrative. In other embodiments, the display panel 200A may have any suitable sub-pixel arrangement pattern, such as a PenTile arrangement.

FIG. 2B is a plan view schematically showing a display panel 200B according to an embodiment of the present disclosure.

Compared with the display panel 200A, in addition to the green sub-pixels G including first and second types of sub-pixels G1 and G2, the red sub-pixels R in the display panel 200B also include first and second types of sub-pixels R1 and R2. A transport layer (specifically, a hole transport layer 104 and/or an electron transport layer 105) of the first type of red sub-pixel R1 has a third thickness, and a transport layer (specifically, a hole transport layer 104 and/or an electron transport layer 105) of the second type of red sub-pixel R2 has a fourth thickness.

The fourth thickness is different from the third thickness. In some embodiments, an absolute value of a difference between the third thickness and the fourth thickness is less than 220 angstroms. In some embodiments, the absolute value of the difference between the third thickness and the fourth thickness is in a range from 110 angstroms to 132 angstroms.

In the example of FIG. 2B, the first type of red sub-pixels R1 are arranged into a plurality of third sub-arrays 210c, each of which includes one respective sub-pixel of the first type of red sub-pixels R1. The second type of red sub-pixels R2 are arranged into a plurality of fourth sub-arrays 210d, each of which includes one respective sub-pixel of the second type of red sub-pixels R2. The plurality of third sub-arrays 210c and the plurality of fourth sub-arrays 210d are alternately arranged in both the first direction D1 and the second direction D2.

Due to different transport layer thicknesses, the microcavities formed by the first and second types of red sub-pixels R1 and R2 have different vertical sizes. This may adjust the color shift curve of a single color (specifically, red), and thus is expected to improve the color shift of mixed colors.

FIG. 2C is a plan view schematically showing a display panel 200C according to an embodiment of the present disclosure.

Compared with the display panel 200B, in addition to the green and red sub-pixels G and R including respective first and second types of sub-pixels, the blue sub-pixels B in the display panel 200C also include first and second types of sub-pixels B1 and B2. A transport layer (specifically, a hole transport layer 104 and/or an electron transport layer 105) of the first type of blue sub-pixel B1 has a fifth thickness, and a transport layer (specifically, a hole transport layer 104 and/or an electron transport layer 105) of the second type of blue sub-pixel B2 has a sixth thickness.

The sixth thickness is different from the fifth thickness. In some embodiments, an absolute value of a difference between the fifth thickness and the sixth thickness is less than 220 angstroms. In some embodiments, the absolute value of the difference between the fifth thickness and the sixth thickness is in a range from 110 angstroms to 132 angstroms.

In the example of FIG. 2C, the first type of blue sub-pixels B1 are arranged into a plurality of fifth sub-arrays 210e, each of which includes one respective sub-pixel of the first type of blue sub-pixels B1. The second type of blue sub-pixels B2 are arranged into a plurality of sixth sub-arrays 210f, each of which includes one respective sub-pixel of the second type of blue sub-pixels B2. The plurality of fifth sub-arrays 210e and the plurality of sixth sub-arrays 210f are alternately arranged in both the first direction D1 and the second direction D2.

Due to different transport layer thicknesses, the microcavities formed by the first and second types of blue sub-pixels B1 and B2 have different vertical sizes. This may adjust the color shift curve of a single color (specifically, blue), and thus is expected to improve the color shift of the mixed colors.

In the embodiments of FIGS. 2A to 2C, the first thickness, the third thickness and the fifth thickness may be equal or different, and the second thickness, the fourth thickness and the sixth thickness may be equal or different.

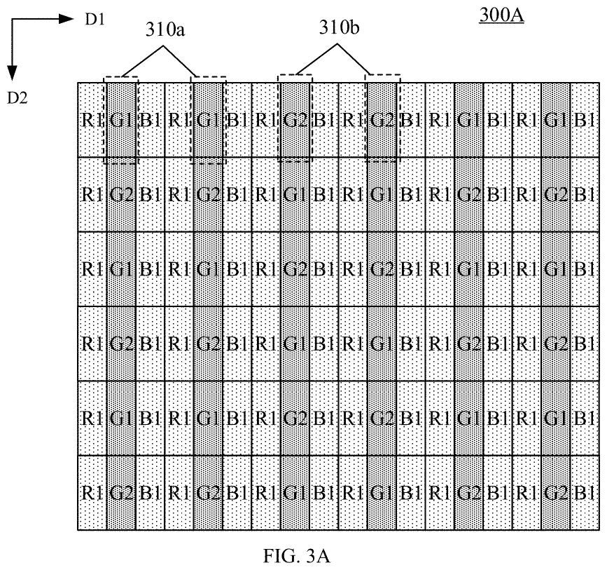

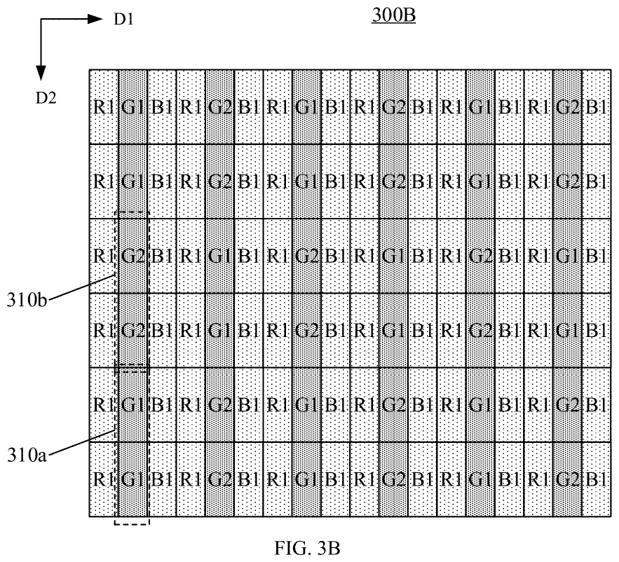

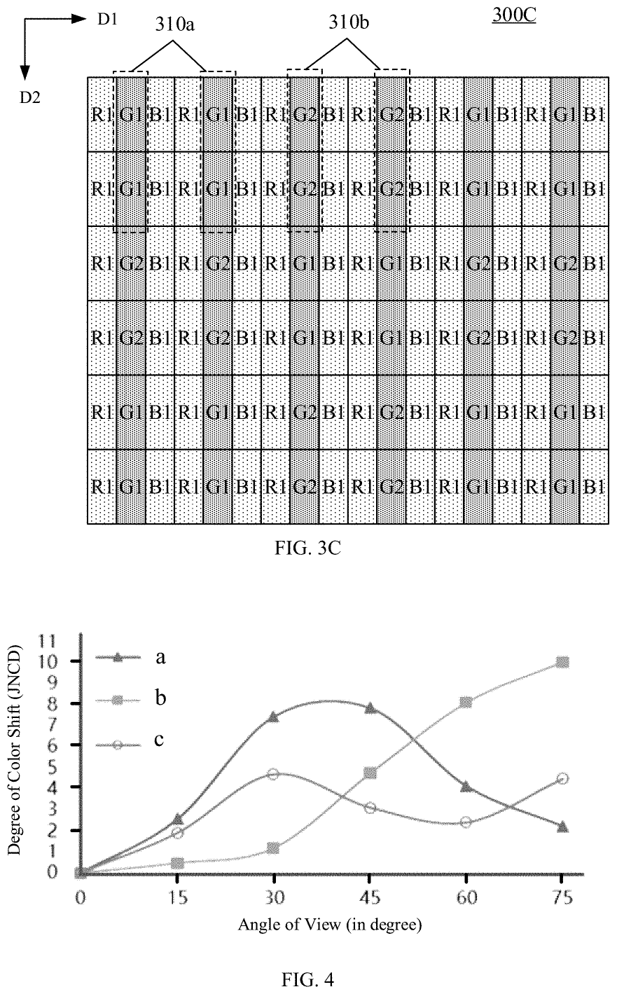

FIG. 3A is a plan view schematically showing a display panel 300A according to an embodiment of the present disclosure.

Referring to FIG. 3A, the first type of green color sub-pixels G1 are arranged into a plurality of first sub-arrays 310a, each of which includes two respective sub-pixels, adjacent in the direction D1, of the first type of green sub-pixels G1. The second type of green color sub-pixels G2 are arranged into a plurality of second sub-arrays 310b, each of which includes two respective sub-pixels, adjacent in the direction D1, of the second type of green sub-pixels G2. The plurality of first sub-arrays 310a and the plurality of second sub-arrays 310b are alternately arranged in both the first direction D1 and the second direction D2.

Although not shown, in other embodiments, each first sub-array 310a may include more than two green sub-pixels G1 of the first type adjacent in the first direction D1, and each second sub-array 310b may include more than two green sub-pixels G2 of the second type adjacent in the first direction D1.

In this context, the phrase “adjacent green sub-pixels G1 of the first type” means that no green sub-pixel G2 of the second type exists between these two green sub-pixels G1 of the first type, regardless of whether there are subpixels of other colors in between. Similarly, the phrase “adjacent green sub-pixel G2 of the second type” means that no green sub-pixel G1 of the first type exists between these two green sub-pixels G2 of the second type, regardless of whether there are sub-pixels of other colors in between. This definition applies, mutatis mutandis, to sub-pixels of other colors. For example, the phrase “adjacent red sub-pixels R1 of the first type” means that no red sub-pixel R2 of the second type exists between these two red sub-pixels R1 of the first type, regardless of whether there are sub-pixels of other colors in between.

FIG. 3B is a plan view schematically showing a display panel 300B according to an embodiment of the present disclosure.

Referring to FIG. 3B, the first type of green sub-pixels G1 are arranged into a plurality of first sub-arrays 310a, each of which includes two respective sub-pixels, adjacent in the direction D2, of the first type of green sub-pixels G1. The second type of green color sub-pixels G2 are arranged into a plurality of second sub-arrays 310b, each of which includes two respective sub-pixels, adjacent in the second direction D2, of the second type of green sub-pixels G2. The plurality of first sub-arrays 310a and the plurality of second sub-arrays 310b are alternately arranged in both the first direction D1 and the second direction D2.

Although not shown, in other embodiments, each first sub-array 310a may include more than two green sub-pixels G1 of the first type adjacent in the second direction D2, and each second sub-array 310b may include more than two green sub-pixels G2 of the second type adjacent in the second direction D2.

FIG. 3C is a plan view schematically showing a display panel 300C according to an embodiment of the present disclosure.

Referring to FIG. 3C, the first type of green color sub-pixels G1 are arranged into a plurality of first sub-arrays 310a, each of which includes an array of respective 2×2 sub-pixels of the first type of green sub-pixels G1, with the respective 2×2 sub-pixels being adjacent to each other in the first direction D1 and the second direction D2. The second type of green sub-pixels G2 are arranged into a plurality of second sub-arrays 310b, each of which includes an array of respective 2×2 sub-pixels of the second type of green sub-pixels G2, with the respective 2×2 sub-pixels being adjacent to each other in the first direction D1 and the second direction D2. The plurality of first sub-arrays 310a and the plurality of second sub-arrays 310b are alternately arranged in both the first direction D1 and the second direction D2.

More generally, each first sub-array 310a may include an array of m×n respective sub-pixels (m≥2, n≥2) of the first type of green sub-pixels G1, with the m×n respective sub-pixels being adjacent to each other in the first direction D1 and the second direction D2. Each second sub-array 310b may include an array of m×n respective sub-pixels of the second type of green sub-pixels G1, with the m×n respective sub-pixels being adjacent to each other in the first direction D1 and the second direction D2.

It will be understood that, although not shown, in other embodiments, the red sub-pixels R and the blue sub-pixels B may be arranged in a same pattern as any one of the patterns of the green sub-pixels G described above with respect to FIGS. 3A to 3C.

In some embodiments, the first and second types of red sub-pixels R1 and R2 may be arranged in a same pattern as the pattern of the first and second types of green sub-pixels G1 and G2 in FIG. 3A. In such an embodiment, each third sub-array of the first type of red sub-pixels R1 includes respective two red sub-pixels R1 of the first type adjacent in the first direction D1, and each fourth sub-array of the second type of red sub-pixels R2 includes respective two red sub-pixels R2 of the second type adjacent in the first direction D1.

In some embodiments, the first and second types of red sub-pixels R1 and R2 may be arranged in a same pattern as the pattern of the first and second types of green sub-pixels G1 and G2 in FIG. 3B. In such an embodiment, each third sub-array of the first type of red sub-pixels R1 includes respective two red sub-pixels R1 of the first type adjacent in the second direction D2, and each fourth sub-array of the second type of red sub-pixels R2 includes respective two red sub-pixels R2 of the second type adjacent in the second direction D2.

In some embodiments, the first and second types of red sub-pixels R1 and R2 may be arranged in a same pattern as the pattern of the first and second types of green sub-pixels G1 and G2 in FIG. 3C. In such an embodiment, each third sub-array of the first type of red sub-pixels R1 includes an array of m×n respective sub-pixels of the first type of red sub-pixels R1, and each fourth sub-array of the second type of red sub-pixels R2 includes an array of m×n respective sub-pixels of the second type of red sub-pixels R2.

In some embodiments, the first and second types of blue sub-pixels B1 and B2 may be arranged in a same pattern as the pattern of the first and second types of green sub-pixels G1 and G2 in FIG. 3A. In such an embodiment, each fifth sub-array of the first type of blue sub-pixels B1 includes respective two blue sub-pixels B1 of the first type adjacent in the first direction D1, and each sixth sub-array of the second type of blue sub-pixels B2 includes respective two blue sub-pixels B2 of the second type adjacent in the first direction D1.

In some embodiments, the first and second types of blue sub-pixels B1 and B2 may be arranged in the same pattern as the pattern of the first and second types of green sub-pixels G1 and G2 in FIG. 3B. In such an embodiment, each fifth sub-array of the first type of blue sub-pixels B1 includes respective two blue sub-pixels B1 of the first type adjacent in the second direction D2, and each sixth sub-array of the second type of blue sub-pixels B2 includes respective two blue sub-pixels B2 of the second type adjacent in the second direction D2.

In some embodiments, the first and second types of blue sub-pixels B1 and B2 may be arranged in the same pattern as the pattern of the first and second types of green sub-pixels G1 and G2 in FIG. 3C. In such an embodiment, each fifth sub-array of the first type of blue sub-pixels B1 includes an array of m×n respective sub-pixels of the first type of blue sub-pixels B1, and each sixth sub-array of the second type of blue sub-pixels B2 includes an array of m×n respective sub-pixels of the second type of blue sub-pixels B2.

It will further be understood that a pattern of the green sub-pixels G, a pattern of the reds sub-pixel R, and a pattern of the blue sub-pixels B may be arbitrarily combined as needed without departing from the scope of the present disclosure.

FIGS. 4 to 6 are schematic diagrams showing improvement in color shift of the display panel 200A of FIG. 2A compared to a conventional display panel. In these figures, the abscissa represents an angle of view, that is, the angle between a viewing direction and the normal of the display panel, and the ordinate represents a degree of color shift (Just Noticeable Color Difference, JNCD).

In FIG. 4, curve ‘a’ represents a green color shift curve of the display panel in which the thicknesses of the hole transport layers in the green sub-pixels are all d1, and curve b represents a green color shift curve of the display panel in which the thicknesses of the hole transport layers in the green sub-pixels are all d2 (d1>d2), and curve ‘c’ represents a green color shift curve of the display panel in which hole transport layers in the first and second types of green sub-pixels that are alternately arranged have thicknesses of d1 and d2, respectively. It can be seen from FIG. 4 that the degree of color shift indicated by the curve ‘c’ is relatively uniform at every angle of view, and has a low value. This demonstrates that the monochrome color shift curve is improved by adjusting the thickness of a transport layer.

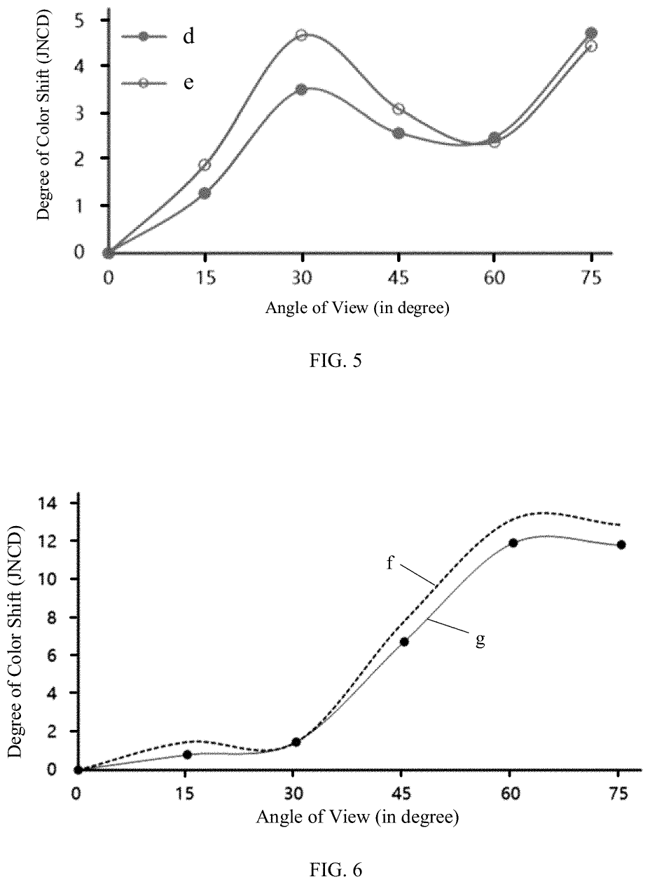

In FIG. 5, curve ‘d’ represents a monochrome color shift curve of the display panel in which the first and second types of green sub-pixels are alternately arranged, and curve ‘e’ represents a monochrome color shift curve of the display panel in which the transport layers in the green sub-pixels have the same thickness. It can be seen from the comparison that the degree of color shift of the curve ‘d’ is low at every angle of view. This demonstrates that alternating variation of the thicknesses of transport layers allows to improve the monochrome color shift phenomenon of the display panel.

In FIG. 6, curve ‘g’ represents a white color shift curve of the display panel in which the first and second types of green sub-pixels are alternately arranged, and curve ‘f’ represents a white color shift curve of a display panel in which the transport layers in the green sub-pixels have the same thickness. It can be seen from the comparison that the degree of color shift of the curve ‘g’ is low at every angle of view. This demonstrates that alternating variation of the thicknesses of transport layers allows to improve the white color shift phenomenon of the display panel.

Table 1 below gives specific data for curves in FIGS. 5 and 6. It can be seen from Table 1 that the display panel in which the thicknesses of the transport layers change alternately has a low degree of color shift in terms of the degree of monochrome color shift and the degree of white color shift.

TABLE 1

| | Degree of green color shift | | Degree of white color shift | |
|---|---|---|---|---|
| Angle of | (JNCD) | | (JNCD) | |
| view (deg.) | Curve e | Curve d | Curve f | Curve g |
| 15 | 1.9 | 1.3 | 1.5 | 0.8 |
| 30 | 4.6 | 3.6 | 1.4 | 1.5 |
| 45 | 3.0 | 2.8 | 7.8 | 6.8 |
| 60 | 2.5 | 2.4 | 13.2 | 12.0 |

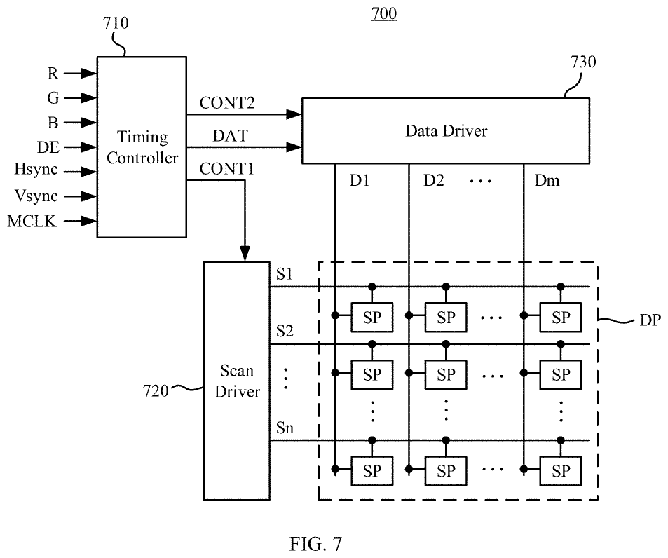

FIG. 7 is a block diagram schematically showing a display apparatus 700 according to an embodiment of the present disclosure.

Referring to FIG. 7, the display apparatus 700 includes a timing controller 710, a scan driver 720, a data driver 730, and a display panel DP.

The display panel DP includes a plurality of sub-pixels SP arranged substantially in a matrix form. In the display panel DP, a plurality of substantially parallel scan lines S1 to Sn extend along a row direction, and a plurality of substantially parallel data lines D1 to Dm extend along a column direction. The scan lines S1 to Sn and the data lines D1 to Dm are coupled to corresponding sub-pixels SP.

The timing controller 710 receives synchronization signals and video signals R, G and B from a system interface. The synchronization signals include a horizontal synchronization signal Hsync, a vertical synchronization signal Vsync, a main clock signal MCLK, and a data enable signal DE. The video signals R, G and B contain luminance information for each of the plurality of pixels SP, where the luminance has a predetermined number of gray scales, for example, 1024 (=2¹⁰), 256 (=2⁸), or 64 (=2⁶) gray scales. The timing controller 710 generates a first driving control signal CONT1, a second driving control signal CONT2, and an image data signal DAT according to the video signals R, G and B, the horizontal synchronization signal Hsync, the vertical synchronization signal Vsync, the data enable signal DE, and the main clock signal MCLK. The first driving control signal CONT1 includes a frame start signal FLM, a first clock signal SCLK1, and a second clock signal SCLK2. The frame start signal FLM may be a signal that generates a first scan signal S[1] for displaying a single frame image. The first clock signal SCLK1 and the second clock signal SCLK2 are synchronization signals configured to sequentially generate the scan signals S[1]-S[n] and apply them to respective sub-pixels of the scanning lines S1-Sn. The timing controller 710 divides the video signals R, G and B into units of frames according to the vertical synchronization signal Vsync, and divides the video signals R, G and B into units of data lines according to the horizontal synchronization signal Hsync, thus generating the image data signal DAT. The timing controller 710 transmits the image data signal DAT and the second driving control signal CONT2 to the data driver 730.

The scan driver 720 is coupled to the scan lines S1-Sn, and generates a plurality of corresponding scan signals S[1] to S[n] according to the first driving control signal CONT1. The scan driver 720 may sequentially apply the scan signals S[1]-S[n] to the scan lines S1-Sn.

The data driver 730 is coupled to the data lines D1-Dm, samples and holds the image data signal DAT according to the second driving control signal CONT2, and applies a plurality of data signals D[1] to D[m] to the data lines D1 to Dm, respectively. By applying the data signals D[1] to D[m] having a set voltage range to the data lines D1 to Dm according to the scan signals S[1] to S[n] that are respectively applied to the scan lines S1 to Sn and have a gate-on voltage, the data driver 730 may program data to the pixels SP.

The display apparatus 700 may be any product or component having a display function, examples of which include, but are not limited to, a mobile phone, a tablet computer, a television, a display, a notebook computer, a digital photo frame, and a navigator. The display apparatus 700 has the same advantages as those of the display panel embodiments described above, which will not be repeated here.

Although the foregoing discussion contains several specific implementation details, these should not be construed as limitations on the scope of the disclosure, but rather as descriptions of features that may be limited to particular embodiments. Certain features that are described in different embodiments in this specification may also be implemented in combination in a single embodiment. In contrast, different features described in a single embodiment may also be implemented in multiple embodiments separately or in any suitable sub-combination. In addition, although a feature may be described as functioning in a particular combination, and even so initially claimed, one or more features from a claimed combination may be excluded from that combination in some cases, and the claimed combination can be directed to a sub-combination or a modification of the sub-combination.

Various modifications and variations can be made by those skilled in the art to the present disclosure without departing from the scope of the present disclosure. If these modifications and variations fall within the scope of the claims of the present disclosure and equivalents thereof, these modifications and variations are intended to be encompassed by the present disclosure.

1. A display panel comprising:
first color sub-pixels, second color sub-pixels and third color sub-pixels in an array arranged in a first direction and a second direction intersecting the first direction,
each of the first, second and third color sub-pixels comprising an anode, a cathode opposite to the anode in a thickness direction of the display panel, and a hole transport layer, a light emitting layer, and an electron transport layer sandwiched between the anode and the cathode and stacked one by one,
wherein the first color sub-pixels comprise a first type in which a first transport layer has a first thickness, and a second type in which the first transport layer has a second thickness, the second thickness being different from the first thickness,
wherein the first transport layer comprises at least one selected from a group consisting of the hole transport layer and the electron transport layer,
wherein the first type of the first color sub-pixels are arranged into a plurality of first sub-arrays, each of the first sub-arrays comprising at least one respective sub-pixel of the first type of the first color sub-pixels,
wherein the second type of the first color sub-pixels are arranged into a plurality of second sub-arrays, each of the second sub-arrays comprising at least one respective sub-pixel of the second type of the first color sub-pixels, and
wherein the plurality of first sub-arrays and the plurality of second sub-arrays are alternately arranged in the first direction and the second direction.

2. The display panel of claim 1,
wherein the at least one respective sub-pixel of each of the plurality of first sub-arrays comprises one respective sub-pixel of the first type of the first color sub-pixels, and
wherein the at least one respective sub-pixel of each of the plurality of second sub-arrays comprises one respective sub-pixel of the second type of the first color sub-pixels.

3. The display panel of claim 1,
wherein the at least one respective sub-pixel of each of the plurality of first sub-arrays comprises at least two respective sub-pixels, adjacent in the first direction, of the first type of the first color sub-pixels, and
wherein the at least one respective sub-pixel of each of the plurality of second sub-arrays comprises at least two respective sub-pixels, adjacent in the first direction, of the second type of the first color sub-pixels.

4. The display panel of claim 1,
wherein the at least one respective sub-pixel of each of the plurality of first sub-arrays comprises at least two respective sub-pixels, adjacent in the second direction, of the first type of the first color sub-pixels, and
wherein the at least one respective sub-pixel of each of the plurality of second sub-arrays comprises at least two respective sub-pixels, adjacent in the second direction, of the second type of the first color sub-pixels.

5. The display panel of claim 1,
wherein the at least one respective sub-pixel of each of the plurality of first sub-arrays comprises an array of m×n respective sub-pixels of the first type of the first color sub-pixels, wherein the m×n respective sub-pixels of the first type of the first color sub-pixels are adjacent to each other in the first direction and the second direction,
wherein the at least one respective sub-pixel of each of the plurality of second sub-arrays comprises an array of m×n respective sub-pixels of the second type of the first color sub-pixels, wherein the m×n respective sub-pixels of the second type of the first color sub-pixels are adjacent to each other in the first direction and the second direction, and
wherein m≥2 and n≥2.

6. The display panel of claim 1, wherein an absolute value of a difference between the first thickness and the second thickness is less than about 220 angstroms.

7. The display panel of claim 1,
wherein the second color sub-pixels comprise a first type in which the first transport layer has a third thickness, and a second type in which the first transport layer has a fourth thickness, the fourth thickness being different from the third thickness,
wherein the first type of the second color sub-pixels are arranged into a plurality of third sub-arrays, each of the third sub-arrays comprising at least one respective sub-pixel of the first type of the second color sub-pixels,
wherein the second type of the second color sub-pixels are arranged into a plurality of fourth sub-arrays, each of the fourth sub-arrays comprising at least one respective sub-pixel of the second type of the second color sub-pixels, and
wherein the plurality of third sub-arrays and the plurality of fourth sub-arrays are alternately arranged in the first direction and the second direction.

8. The display panel of claim 7,
wherein the at least one respective sub-pixel of each of the third sub-arrays comprises one respective sub-pixel of the first type of the second color sub-pixels, and
wherein the at least one respective sub-pixel of each of the fourth sub-arrays comprises one respective sub-pixel of the second type of the second color sub-pixels.

9. The display panel of claim 7,
wherein the at least one respective sub-pixel of each of the third sub-arrays comprises at least two respective sub-pixels, adjacent in the first direction, of the first type of the second color sub-pixels, and
wherein the at least one respective sub-pixel of each of the fourth sub-arrays comprises at least two respective sub-pixels, adjacent in the first direction, of the second type of the second color sub-pixels.

10. The display panel of claim 7,
wherein the at least one respective sub-pixel of each of the third sub-arrays comprises at least two respective sub-pixels, adjacent in the second direction, of the first type of the second color sub-pixels, and
wherein the at least one respective sub-pixel of each of the fourth sub-arrays comprises at least two respective sub-pixels, adjacent in the second direction, of the second type of the second color sub-pixels.

11. The display panel of claim 7,
wherein the at least one respective sub-pixel of each of the third sub-arrays comprises an array of m×n respective sub-pixels of the first type of the second color sub-pixels, wherein the m×n respective sub-pixels of the first type of the second color sub-pixels are adjacent to each other in the first direction and the second direction,
wherein the at least one respective sub-pixel of each of the fourth sub-arrays comprises an array of m×n respective sub-pixels of the second type of the second color sub-pixels, wherein the m×n respective sub-pixels of the second type of the second color sub-pixels are adjacent to each other in the first direction and the second direction, and
wherein m≥2 and n≥2.

12. The display panel of claim 7, wherein an absolute value of a difference between the third thickness and the fourth thickness is less than about 220 angstroms.

13. The display panel of claim 7,
wherein the third color sub-pixels comprise a first type in which the first transport layer has a fifth thickness, and a second type in which the first transport layer has a sixth thickness, the sixth thickness being different from the fifth thickness,
wherein the first type of the third color sub-pixels are arranged into a plurality of fifth sub-arrays, each of the fifth sub-arrays comprising at least one respective sub-pixel of the first type of the third color sub-pixels,
wherein the second type of the third color sub-pixels are arranged into a plurality of sixth sub-arrays, each of the sixth sub-arrays comprising at least one respective sub-pixel of the second type of the third color sub-pixels, and
wherein the plurality of fifth sub-arrays and the plurality of sixth sub-arrays are alternately arranged in the first direction and the second direction.

14. The display panel of claim 13,
wherein the at least one respective sub-pixel of each of the fifth sub-arrays comprises one respective sub-pixel of the first type of the third color sub-pixels, and
wherein the at least one respective sub-pixel of each of the sixth sub-arrays comprises one respective sub-pixel of the second type of the third color sub-pixels.

15. The display panel of claim 13,
wherein the at least one respective sub-pixel of each of the fifth sub-arrays comprises at least two respective sub-pixels, adjacent in the first direction, of the first type of the third color sub-pixels, and
wherein the at least one respective sub-pixel of each of the sixth sub-arrays comprises at least two respective sub-pixels, adjacent in the first direction, of the second type of the third color sub-pixels.

16. The display panel of claim 13,
wherein the at least one respective sub-pixel of each of the fifth sub-arrays comprises at least two respective sub-pixels, adjacent in the second direction, of the first type of the third color sub-pixels, and
wherein the at least one respective sub-pixel of each of the sixth sub-arrays comprises at least two respective sub-pixels, adjacent in the second direction, of the second type of the third color sub-pixels.

17. The display panel of claim 13,
wherein the at least one respective sub-pixel of each of the fifth sub-arrays comprises an array of m×n respective sub-pixels of the first type of the third color sub-pixels, wherein the m×n respective sub-pixels of the first type of the third color sub-pixels are adjacent to each other in the first direction and the second direction,
wherein the at least one respective sub-pixel of each of the sixth sub-arrays comprises an array of m×n respective sub-pixels of the second type of the third color sub-pixels, wherein the m×n respective sub-pixels of the second type of the third color sub-pixels are adjacent to each other in the first direction and the second direction, and
wherein m≥2 and n≥2.

18. The display panel of claim 13, wherein an absolute value of a difference between the fifth thickness and the sixth thickness is less than about 220 angstroms.

19. The display panel of claim 1, wherein the first color sub-pixels, the second color sub-pixels, and the third color sub-pixels comprise respective different colors selected from red, green, and blue.

20. A display apparatus comprising the display panel of claim 1.
